(19) United States
(12) Patent Application Publication
(10) Pub. No.: US 2021/0298200 A1
(43) Pub. Date: Sep. 23, 2021

(54) ELECTRONIC DEVICE AND AIRFLOW CONTROL METHOD

(71) Applicant: SONY CORPORATION, Tokyo (JP)

(72) Inventors: SATOSHI MIKI, TOKYO (JP); TAKAYUKI SAKAMOTO, KANAGAWA (JP); YUUJI TAKIMOTO, KANAGAWA (JP)

(21) Appl. No.: 16/316,117

(22) PCT Filed: Jul. 13, 2017
(86) PCT No.: PCT/JP2017/025501

§ 371 Date: Jan. 8, 2019

(30) Foreign Application Priority Data
Jul. 27, 2016 (JP) 2016-147022

(51) Int. Cl. H05K 7/20; F21V 29/61; G03B 21/16; G03B 17/55; G01N 21/53; G01K 1/14; G06K 9/00

(52) U.S. Cl. CPC H05K 7/20209; F21V 29/61; G03B 21/16; H05K 7/20136; H04N 13/239; G01N 21/53; G01K 1/14; G06K 9/00624; G03B 17/55

(57) ABSTRACT

The present disclosure relates to an electronic device and an airflow control method that are capable of prevent adhesion of a smoke constituent to an optical component such as a lens.

An electronic device according to one aspect of the present disclosure includes: a heat release fan configured to release heat generated inside a housing; an optical component installed at a position corresponding to an opening formed in the housing; a smoke detection unit configured to detect smoke; and a control unit configured to control, in a case where smoke is detected by the smoke detection unit, the heat release fan to discharge air through the opening at which the optical component is installed. The present disclosure is applicable to, for example, a ceiling light including a built-in projector.

### TECHNICAL FIELD

The present disclosure relates to an electronic device and an airflow control method, and particularly relates to an electronic device and an airflow control method that are capable of preventing adhesion of a smoke constituent to an optical component such as a lens attached to the electronic device.

### BACKGROUND ART

Conventionally, there has been disclosed a projector installed on a ceiling and configured to project video onto a floor, a table, or the like directly below. In addition, a configuration in which the projector is built in an illumination apparatus installed on a ceiling has been disclosed (refer to Patent Document 1, for example).

### CITATION LIST

### Patent Document

Patent Document 1: WO2015/098188

### SUMMARY OF THE INVENTION

### Problems to be Solved by the Invention

A projector built in an illumination apparatus is used in environment under conditions where, for example, the illumination apparatus is exposed to steam and smoke such as oil smoke, sooty smoke, tobacco smoke, and dust. Among these conditions, in a case where the projector is exposed to smoke, any constituent of the smoke adheres to a projection lens of the projector and contaminates the projection lens, which potentially degrades the image quality of projected video.

The present disclosure is intended to solve the above-described problem and prevent adhesion of a smoke constituent to an optical component such as a lens included in an electronic device.

### Solutions to Problems

An electronic device according to one aspect of the present disclosure includes: a heat release fan configured to release heat generated inside a housing; an optical component installed at a position corresponding to an opening formed in the housing; a smoke detection unit configured to detect smoke; and a control unit configured to control, in a case where smoke is detected by the smoke detection unit, the heat release fan to discharge air through the opening at which the optical component is installed.

The electronic device according to one aspect of the present disclosure may further include a temperature detection unit configured to detect temperature inside the housing. The control unit may control the heat release fan also on the basis of a result of the detection by the temperature detection unit.

The control unit may control at least one of a rotational direction or a rotational speed of the heat release fan.

The control unit may control the rotational direction of the heat release fan to discharge air through the opening at which the optical component is installed in a case where the detected temperature is equal to or higher than a threshold and smoke is detected.

The control unit may control the rotational direction of the heat release fan to take in air through the opening at which the optical component is installed in a case where the detected temperature is equal to or higher than a threshold and no smoke is detected.

The opening may be formed at a lower part of the housing, and the optical component may be installed facing downward.

The smoke detection unit may detect at least one of oil smoke, sooty smoke, tobacco smoke, or dust.

The optical component may be a lens.

The electronic device according to one aspect of the present disclosure may further include a heat source that potentially generates heat by performing predetermined processing. The control unit may further restrict operation of the heat source on the basis of a result of the detection by the temperature detection unit.

The electronic device according to one aspect of the present disclosure may further include a projector unit configured to project video in a predetermined direction.

The electronic device according to one aspect of the present disclosure may further include: an image capturing unit configured to capture an image in a predetermined direction; and a signal processing unit configured to identify an object included in the captured image. The control unit may control the heat release fan also on the basis of a result of the identification by the signal processing unit.

The electronic device according to one aspect of the present disclosure may further include an illumination unit configured to project light in a predetermined direction.

An airflow control method according to one aspect of the present disclosure is an airflow control method for an electronic device including: a heat release fan configured to release heat generated inside a housing; and an optical component installed at a position corresponding to an opening formed in the housing. The method includes: a smoke detection step of detecting smoke; and a control step of controlling the heat release fan to discharge air through the opening at which the optical component is installed in a case where smoke is detected at the smoke detection step. The steps are executed by the electronic device.

According to one aspect of the present disclosure, the heat release fan is controlled to discharge air through the opening at which the optical component is installed in a case where smoke is detected.

### Effects of the Invention

According to one aspect of the present disclosure, it is possible to prevent adhesion of a smoke constituent to an optical component.

### BRIEF DESCRIPTION OF DRAWINGS

FIG. 1 is a diagram illustrating use environment of an illumination apparatus to which the present disclosure is applied.

FIG. 2 is a block diagram illustrating an exemplary configuration of the illumination apparatus.

FIG. 3 is a front view of this illumination apparatus 10 in the case of being viewed from below.

FIG. 4 is a cross-sectional view illustrating the exemplary configuration of the illumination apparatus 10.

FIG. 5 is a flowchart for description of heat release control processing.

### MODE FOR CARRYING OUT THE INVENTION

The following describes a best mode (hereinafter referred to as an embodiment) for carrying out the present disclosure in detail with reference to the accompanying drawings.

<Illumination Apparatus as an Embodiment of the Present Disclosure>

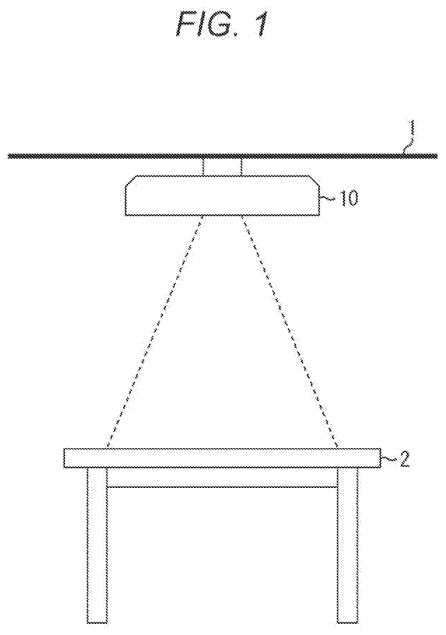

FIG. 1 illustrates use environment of an illumination apparatus as an embodiment of the present disclosure. This illumination apparatus 10 is supposed to be installed on a ceiling 1, and has a projector function to project video or the like onto a table 2 directly below the illumination apparatus 10.

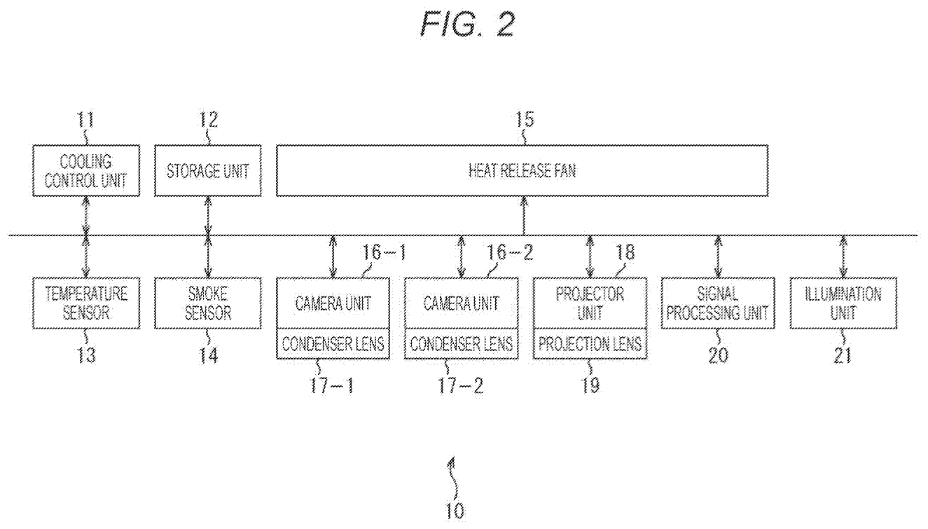

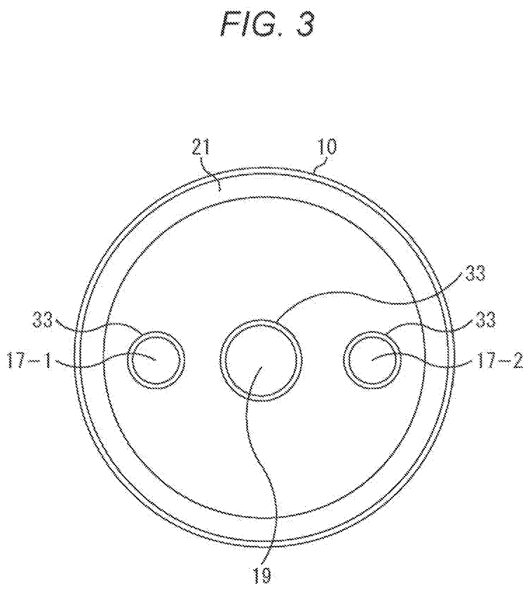

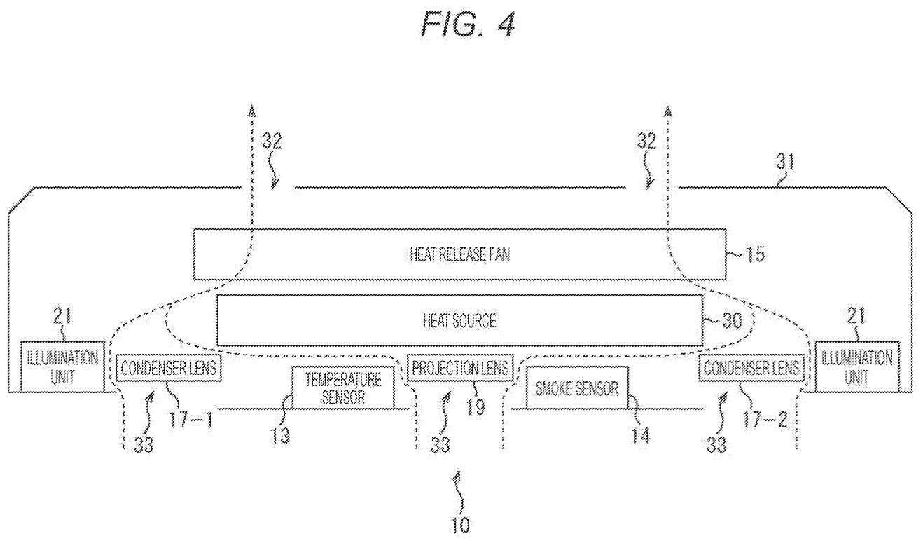

FIG. 2 is a block diagram illustrating an exemplary configuration of the illumination apparatus 10. FIG. 3 is a front view of the illumination apparatus 10 installed on the ceiling in the case of being viewed from below. FIG. 4 is a cross-sectional view illustrating the exemplary configuration of the illumination apparatus 10.

As illustrated in FIG. 2, the illumination apparatus 10 includes a cooling control unit 11, a storage unit 12, a temperature sensor 13, a smoke sensor 14, and a heat release fan 15. The illumination apparatus 10 further includes camera units 16-1 and 16-2, a projector unit 18, a signal processing unit 20, and an illumination unit 21.

The cooling control unit 11 is achieved by a control circuit such as a CPU, controls rotation of the heat release fan 15 on the basis of results of detection by the temperature sensor 13 and the smoke sensor 14, and restricts operations of an image capturing unit 16, the projector unit 18, and the signal processing unit 20, which are a heat source 30 (FIG. 4). The storage unit 12 stores a computer program executed by the cooling control unit 11 and various kinds of data.

The temperature sensor 13 detects temperature inside a housing 31 (FIG. 14) of the illumination apparatus 10. The smoke sensor 14 detects smoke such as oil smoke, sooty smoke, tobacco smoke, and dust around the housing 31 of the illumination apparatus 10. Note that the smoke sensor 14 may be capable of detecting not only the existence of smoke but also the concentration thereof. In addition, the smoke sensor 14 may detect gas such as steam containing a constituent such as oil that adheres to a lens.

The heat release fan 15 rotates forwardly or backwardly in accordance with control of the cooling control unit 11 to externally release heat generated inside the housing 31, thereby cooling inside of the housing 31. The direction of the forward rotation is defined to be a direction in which air is taken into the housing 31 through a lower opening 33 and discharged upward through an upper opening 32 as illustrated in FIG. 4. The direction of the backward rotation is defined to be a direction in which air is taken into the housing 31 through the upper opening 32 and discharged downward through the lower opening 33.

Note that the effect of cooling inside of the housing 31 is higher in a case where the forward rotation is performed than in a case where the backward rotation is performed, and it is controlled to perform the forward rotation in a normal high-temperature condition or perform the backward rotation in a high-temperature condition with smoke sensing. However, the forward rotation and the backward rotation may be defined oppositely. In addition, the upper opening 32 may be formed on a side of the housing 31.

The camera units 16-1 and 16-2 have sensitivity to visible light and invisible light such as IR, function as a stereo camera in the pair, include condenser lenses 17-1 and 17-2, respectively, and are installed in an orientation in which the camera units 16-1 and 16-2 can capture an image below the illumination apparatus 10. Images captured by the camera units 16-1 and 16-2 are supplied to the signal processing unit 20. Hereinafter, the camera units 16-1 and 16-2 and the condenser lenses 17-1 and 17-2 are simply referred to as camera units 16 and condenser lenses 17, respectively, in a case where they need not to be individually distinguished.

Each light condensing lens 17 is disposed at a position corresponding to the lower opening 33 of the housing 31.

The projector unit 18 achieves a projector function, includes a light source element such as a light bulb or a laser, and a projection lens 19, and is installed in an orientation in which the projector unit 18 can project video below the illumination apparatus 10. The projection lens 19 is disposed at a position corresponding to the lower opening 33 of the housing 31. However, a gap is provided between the lower opening 33 and each of the condenser lenses 17 and the projection lens 19 to allow air to be taken in and discharged.

Hereinafter, the condenser lenses 17 and the projection lens 19 outside of the housing 31 are also referred to as optical components.

The signal processing unit 20 is achieved by a signal processing circuit or the like, generates image data to be projected by the projector unit 19, and analyzes a stereo image supplied from the image capturing units 16-1 and 16-2, thereby sensing motion of an object in a three-dimensional direction (for example, a predetermined gesture such as motion that a user vertically moves a hand between the illumination apparatus 10 and the table 2).

For example, the sensed object motion is used as a trigger for changing image data to be projected, and is used to manually (through user operations) control the brightness and color of illumination and operations of the projector unit 18, the heat release fan 15, and the like.

In addition, in a case where the camera units 16 have sensitivity to IR light, the signal processing unit 20 can sense and identify a heat source (for example, a tobacco placed in an ash tray on the table 2, a portable stove burner, a pan, a hot plate, or the like) present in an image capturing range on the basis of image data obtained by the camera units 16. In a case where the heat source is sensed by the signal processing unit 20, too, rotation of the heat release fan 15 may be controlled similarly to cases where temperature and smoke are sensed.

The illumination unit 21 includes, for example, a plurality of LEDs and the like, and can change brightness and color in accordance with operations from the user.

<Heat Release Control Processing Performed by Illumination Apparatus 10>

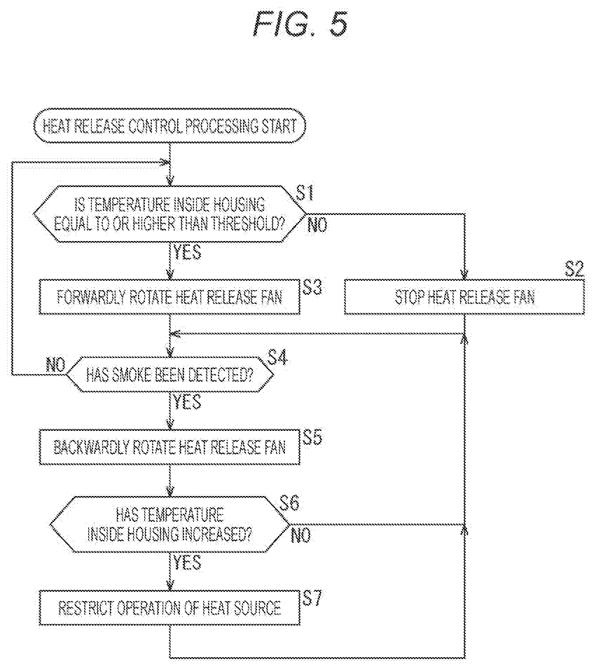

FIG. 5 is a flowchart for description of heat release control processing performed by the cooling control unit 11 of the illumination apparatus 10.

The heat release control processing is continuously executed not only when the projector function of the projector unit 18 is executed but also when the projector function is not executed.

At step S1, the cooling control unit 11 determines whether or not temperature inside the housing 31 is equal to or higher than a predetermined threshold on the basis of a result of detection by the temperature sensor 13. The process proceeds to step S2 in a case where it is determined that the temperature inside the housing 31 is not equal to or higher than the predetermined threshold (is lower than the predetermined threshold).

At step S2, in a case where the heat release fan 15 currently forwardly rotating or backwardly rotating, the cooling control unit 11 stops the heat release fan 15 or reduces the rotational speed thereof. Accordingly, it is possible to prevent fan noise attributable to the rotation of the heat release fan 15. Thereafter, the process proceeds to step S4.

In a case where it is determined that the temperature inside the housing 31 is equal to or higher than the predetermined threshold at step S1, the process proceeds to step S3.

At step S3, the cooling control unit 11 controls the heat release fan 15 to forwardly rotate. Accordingly, heat inside the housing 31 can be most efficiently released upward. Thereafter, the process proceeds to step S4.

At step S4, the cooling control unit 11 determines whether or not smoke has been detected around the housing 31 by the smoke sensor 14. In a case where no smoke has been detected, the process returns to step S1, and the processing at steps S1 and later is repeated. In a case where smoke has been detected, the process proceeds to step S5.

At step S5, the cooling control unit 11 backwardly rotates the heat release fan 15. Accordingly, air flows out through the lower opening 33 of the housing 31, and thus heat inside the housing 31 can be released downward. In addition, accordingly, smoke can be removed from around the optical components (the condenser lenses 17 and the projection lens 19), thereby preventing adhesion of any smoke constituent to the optical components.

At step S6, the cooling control unit 11 determines whether or not the temperature inside the housing 31 has further increased from the level detected at step S1 on the basis of a result of detection by the temperature sensor 13. In a case where it is determined that the temperature inside the housing 31 has further increased, the process proceeds to step S7. At step S7, the cooling control unit 11 restricts operations of the image capturing unit 16, the projector unit 18, and the signal processing unit 20 as the heat source 30.

Specifically, the cooling control unit 11 reduces the frame rate of the image capturing unit 16, decreases the luminance of projection light from the projector unit 18, and decreases the operation clock rate of the signal processing unit 20. Note that decrease of the visibility of a projection image due to decrease of the luminance of projection light from the projector unit 18 can be handled by performing appropriate image correction.

When the operation of the heat source 30 is restricted, heat generation inside the housing 31 is restricted, and further temperature increase is prevented. Thereafter, the process returns to step S4, and the processing at steps S4 and later is repeated.

Note that, in a case where it is that determined the temperature inside the housing 31 has not increased at step S6, the process skips step S7 and returns to step S4, and the processing at steps S4 and later is repeated.

According to the heat release control processing described above, it is possible to most efficiently perform heat release in a case where no smoke is sensed. In addition, in a case where smoke is sensed, it is possible to not only release heat generated inside the housing 31 but also prevent adhesion of a smoke constituent to the optical components.

Accordingly, the user can continuously use the illumination apparatus 10 in a situation where smoke can generate. In addition, it is possible to significantly reduce work of cleaning the optical components by the user. Moreover, there is no need to provide, for example, a lens cover and an oil filter to cover the optical components, and thus manufacturing cost can be reduced as compared to a case where these cover and filter are provided.

Note that, in a case where control is executed to backwardly rotate the heat release fan 15 and restrict the operation of the heat source 30 in accordance with smoke sensing, this control execution may be notified to the user. Specifically, text, a mark, or the like indicating the control execution may be displayed on video projected by the projector unit 18, an indicator including an LED or the like may be provided outside of the housing 31, or alarm sound or the like may be output.

In addition, in the heat release control processing described above, the heat release fan 15 is controlled in three different ways of forward rotation, backward rotation, and stopping, but additionally, the rotational speed of the heat release fan 15 may be controlled in accordance with temperature and the concentration of smoke. In this case, fan noise can be reduced by decreasing the rotation speed of the heat release fan 15 to a necessary minimum.

In a case where the heat release fan 15 is backwardly rotating and temperature increase cannot be stopped by restricting the operation of the heat source 30, cooling inside the housing 31 may be prioritized while allowing adhesion of a smoke constituent to the optical components, and the heat release fan 15 may be forwardly rotated.

Alternatively, the heat release fan 15 may be constantly backwardly rotated in accordance with an operation by the user to reliably prevent adhesion of a smoke constituent to the optical components.

Note that, the present embodiment of the present disclosure is not limited to the illumination apparatus 10, but is applicable to various electronic devices that are used under environment in which smoke can exist and on which optical components are mounted, and various kinds of modifications are possible without departing from the scope of the present disclosure.

The present disclosure may be configured as described below.

(1)

An electronic device including:

a heat release fan configured to release heat generated inside a housing;

an optical component installed at a position corresponding to an opening formed in the housing;

a smoke detection unit configured to detect smoke; and

a control unit configured to control, in a case where smoke is detected by the smoke detection unit, the heat release fan to discharge air through the opening at which the optical component is installed.

(2)

The electronic device according to (1), further including a temperature detection unit configured to detect temperature inside the housing, in which the control unit controls the heat release fan also on the basis of a result of the detection by the temperature detection unit.

(3)

The electronic device according to (1) or (2), in which the control unit controls at least one of a rotational direction or a rotational speed of the heat release fan.

(4)

The electronic device according to (2) or (3), in which the control unit controls the rotational direction of the heat release fan to discharge air through the opening at which the optical component is installed in a case where the detected temperature is equal to or higher than a threshold and smoke is detected.

(5)

The electronic device according to any one of claims (2) to (4), in which the control unit controls the rotational direction of the heat release fan to take in air through the opening at which the optical component is installed in a case where the detected temperature is equal to or higher than a threshold and no smoke is detected.

(6)

The electronic device according to any one of claims (1) to (5), in which

the opening is formed at a lower part of the housing, and

the optical component is installed facing downward.

(7)

The electronic device according to any one of claims (1) to (6), in which the smoke detection unit detects at least one of oil smoke, sooty smoke, tobacco smoke, or dust.

(8)

The electronic device according to any one of claims (1) to (7), in which the optical component is a lens.

(9)

The electronic device according to any one of claims (2) to (8), further including a heat source that potentially generates heat by performing predetermined processing, in which the control unit further restricts operation of the heat source on the basis of a result of the detection by the temperature detection unit.

(10)

The electronic device according to any one of claims (1) to (9), further including a projector unit configured to project video in a predetermined direction.

(11)

The electronic device according to any one of claims (1) to (10), further including:

an image capturing unit configured to capture an image in a predetermined direction; and

a signal processing unit configured to identify an object included in the captured image,

in which the control unit controls the heat release fan also on the basis of a result of the identification by the signal processing unit.

(12)

The electronic device according to any one of claims (1) to (11), further including an illumination unit configured to project light in a predetermined direction.

(13)

An airflow control method for an electronic device including:

a heat release fan configured to release heat generated inside a housing; and

an optical component installed at a position corresponding to an opening formed in the housing,

the method including:

a smoke detection step of detecting smoke; and

a control step of controlling the heat release fan to discharge air through the opening at which the optical component is installed in a case where smoke is detected at the smoke detection step,

in which the steps are executed by the electronic device.

### REFERENCE SIGNS LIST

10 Illumination apparatus
11 Cooling control unit
12 Storage unit
13 Temperature sensor
14 Smoke sensor
15 Heat release fan
16 Image capturing unit
17 Condenser lens
18 Projector unit
19 Projection lens
20 Signal processing unit
21 Illumination unit
31 Housing
32 Upper opening
33 Lower opening

1. An electronic device comprising:
a heat release fan configured to release heat generated inside a housing;
an optical component installed at a position corresponding to an opening formed in the housing;
a smoke detection unit configured to detect smoke; and
a control unit configured to control the heat release fan to discharge air through the opening at which the optical component is installed in a case where smoke is detected by the smoke detection unit.

2. The electronic device according to claim 1, further comprising a temperature detection unit configured to detect temperature inside the housing, wherein the control unit controls the heat release fan also on the basis of a result of the detection by the temperature detection unit.

3. The electronic device according to claim 2, wherein the control unit controls at least one of a rotational direction or a rotational speed of the heat release fan.

4. The electronic device according to claim 2, wherein the control unit controls the rotational direction of the heat release fan to discharge air through the opening at which the optical component is installed in a case where the detected temperature is equal to or higher than a threshold and smoke is detected.

5. The electronic device according to claim 2, wherein the control unit controls the rotational direction of the heat release fan to take in air through the opening at which the optical component is installed in a case where the detected temperature is equal to or higher than a threshold and no smoke is detected.

6. The electronic device according to claim 2, wherein
the opening is formed at a lower part of the housing, and
the optical component is installed facing downward.

7. The electronic device according to claim 2, wherein the smoke detection unit detects at least one of oil smoke, sooty smoke, tobacco smoke, or dust.

8. The electronic device according to claim 2, wherein the optical component is a lens.

9. The electronic device according to claim 2, further comprising a heat source that potentially generates heat by performing predetermined processing, wherein the control unit further restricts operation of the heat source on the basis of a result of the detection by the temperature detection unit.

10. The electronic device according to claim 2, further comprising a projector unit configured to project video in a predetermined direction.

11. The electronic device according to claim 2, further comprising:
an image capturing unit configured to capture an image in a predetermined direction; and
a signal processing unit configured to identify an object included in the captured image,
wherein the control unit controls the heat release fan also on the basis of a result of the identification by the signal processing unit.

12. The electronic device according to claim 2, further comprising an illumination unit configured to project light in a predetermined direction.

13. An airflow control method for an electronic device including:
a heat release fan configured to release heat generated inside a housing; and
an optical component installed at a position corresponding to an opening formed in the housing,
the method comprising:
a smoke detection step of detecting smoke; and
a control step of controlling the heat release fan to discharge air through the opening at which the optical component is installed in a case where smoke is detected at the smoke detection step,
wherein the steps are executed by the electronic device.
